(19) United States
(12) Patent Application Publication
(10) Pub. No.: US 2020/0359519 A1
(43) Pub. Date: Nov. 12, 2020

(54) LOCKING SOLDER BUSH

(71) Applicant: BAE SYSTEMS plc, London (GB)

(72) Inventors: Ian William Pye, Rochester Kent (GB); Steven David Hebdon, Rochester Kent (GB)

(73) Assignee: BAE SYSTEMS plc, London (GB)

(21) Appl. No.: 16/770,326

(22) PCT Filed: Nov. 19, 2018
(86) PCT No.: PCT/GB2018/053343

§ 371 Date: Jun. 5, 2020

(30) Foreign Application Priority Data
Dec. 7, 2017 (GB) 1720374.6

(51) Int. Cl. H05K 7/14; H05K 1/14

(52) U.S. Cl. CPC H05K 7/142; H05K 2201/10984; H05K 1/14

(57) ABSTRACT

A fastener for securing a circuit board to a housing and/or a second circuit board. The fastener includes a locking mechanism that ensures the circuit board is reliably mounted within the housing such that the circuit board is not thermally or physically damaged because of vibrational loosening or overheating.

This disclosure relates to a fastener for securing a circuit board to a housing and/or a second circuit board.

Current fastening means such as bolted joints, for example, have nut and bolt components that are able to clamp objects together. The problem with these sorts of joints is that under vibration, the components can loosen thereby reducing the clamping force on the objects and causing damage to said objects. This is especially true for hardware such as circuit boards in avionics systems.

Thread locking components can be used to help prevent this vibrational loosening, but their use is often restricted by customer specifications.

Solutions disclosed in the prior art include the use of brackets and bushings, but these approaches are complicated, heavy, expensive and designed for insertion into metal. They therefore have limited applications and can be unreliable.

The embodiments described below are not limited to implementations which solve any or all of the disadvantages of known systems.

### SUMMARY

This summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

There is provided a fastener for securing a circuit board to a housing and/or a second circuit board, the fastener comprising: a bush comprising an opening; and a thread part comprising a female thread, the thread part being positioned and retained within the opening of the bush; wherein the bush is for attachment to a circuit board by a soldered joint, and wherein the female thread comprises a locking means for locking a male thread in the female thread.

The bush may be formed of brass with a tin plating.

The thread part may be a helicoil.

The helicoil may be a tang-less helicoil.

The thread part may be a press-fit in the bush.

The thread part may be a screw-fit in the bush.

### BRIEF DESCRIPTION OF THE DRAWINGS

Embodiments will be described, by way of example, with reference to the following drawings, in which:

FIG. 1 shows a perspective view of a fastener;

FIG. 2 shows a plan view of the fastener of FIG. 1; and

FIG. 3 shows a cross-sectional view of the fastener of FIG. 1.

### DETAILED DESCRIPTION

Further details, aspects and embodiments of the disclosure will now be described, by way of example only.

Avionic systems are those used on aircraft, satellites and spacecraft. They include numerous systems that perform individual functions to control, for example, communications, navigation, flight-control, radar, sonar and electro-optics.

These control systems include electronic units comprising circuit boards. These circuit boards must be reliably secured within housings so that they are not thermally or physically damaged as a result of aircraft vibration or overheating.

The fastener of the present disclosure provides a mechanism for mounting circuit boards and overcoming at least some of the difficulties with previous fasteners.

The configuration of the fastener enables a circuit board to be fixed either directly to an external wall of a housing or indirectly via one or more other circuit boards with a convenient installation process by a locking fastener. Thermal contact with the external wall is ensured, thereby aiding natural cooling of the circuit board and avoiding the need for forced ventilation which is undesirable.

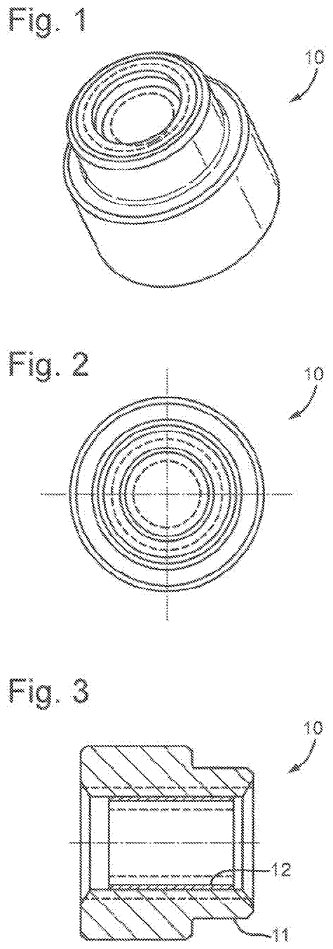

FIGS. 1 to 3 show an example of a fastener providing the above-mentioned function. The fastener 10 consists of two parts, a bush 11 and a thread part 12.

The bush 11 is a hollow lining, which is preferably cylindrical. The bush 11 is formed from a material suitable for joining to a circuit board with a soldered joint. For example, the bush 11 may be formed of brass with a tin plating.

The thread part 12 comprises a female thread including a locking means to lock a male thread received in the female thread. The thread part 12 may be a locking helicoil, for example a tang-less helicoil. Other types of threads and locking means may also be.

The thread part 12 is fixed inside the bush by any suitable means known in the art. In some embodiments, the thread part may be a screw-fit in the bush. In some embodiments, the thread part may be a press-fit in the bush.

In use, the bush is soldered to a circuit board, either by automatic or manual methods. A male threaded fastener is inserted through a wall of a housing or a second circuit board for fixing the circuit board to the wall or the second circuit board. The screw is inserted into the thread part 12 inside the bush of the fastener 10. The male threaded fastener engages with the female thread in the thread part 12, such that the male threaded fastener is locked in position. This results in the circuit board being fixed to the wall of the housing or the second circuit board.

The circuit board can be fixed to a housing, a housing and one or more other circuit boards, or one or more other circuit boards.

The locking mechanism reduces the risk of the male threaded fastener loosening or falling out of the fastener 10 due to vibrations.

Any type of circuit board is suitable for use with the fastener 10 of the disclosure. Furthermore, there is no limitation on the number of fasteners 10 that can be soldered to a circuit board.

The fastener 10 and thread inside the thread part 12 can be of any suitable size according to the application required. For example, the diameter of the bush may be 0.66 cm. The major diameter of the thread part may be 0.29 cm.

1. A fastener for securing a circuit board to a housing and/or a second circuit board, the fastener comprising:
a bush comprising an opening; and
a thread part comprising a female thread, the thread part being positioned and retained within the opening of the bush;
wherein the bush is for attachment to a circuit board by a soldered joint, and
wherein the female thread is configured for locking a male thread in the female thread.

2. The fastener of claim 1, wherein the bush is formed of brass with a tin plating.

3. The fastener of claim 1, wherein the thread part is a helicoil.

4. The fastener of claim 3, wherein the helicoil is a tang-less helicoil.

5. The fastener of claim 1, wherein the thread part is a press-fit in the bush.

6. The fastener of claim 1, wherein the thread part is a screw-fit in the bush.

7. The fastener of claim 1, wherein the fastener is configured to provide thermal contact between the circuit board and the housing and/or between the circuit board and the second circuit board.

8. The fastener of claim 1, wherein the bush has a diameter in the range of about 0.66 cm, and the thread part has a major diameter in the range of about 0.29 cm.

9. An avionic system comprising the fastener of claim 1.

10. A circuit board assembly comprising a circuit board and the fastener of claim 1, wherein the bush is soldered to the circuit board.

11. An electronic system, comprising:
a first circuit board;
a second circuit board; and
a fastener assembly connecting the first circuit board to the second circuit board, the fastener including
a bush comprising an opening and connected to the first circuit board by a soldered joint,
a thread part within the opening of the bush and comprising a female locking thread, and
a screw including a male thread and passing through the second circuit board and engaged with the female thread, such that the male thread is locked in position by the female thread.

12. The electronic system of claim 11, wherein the bush is formed of brass with a tin plating.

13. The electronic system of claim 11, wherein the thread part is a helicoil or a tang-less helicoil.

14. The electronic system of claim 11, wherein the thread part is one of a press-fit in the bush or a screw-fit in the bush.

15. The electronic system of claim 11, wherein the fastener provides thermal contact between: the first and second circuit boards; the first circuit board and a housing having a wall through which the screw passes; the second circuit board and the housing; or each of the first circuit board, the second circuit board, and the housing.

16. An avionic system comprising the electronic system of claim 11.

17. An electronic system, comprising:
a housing having a wall;
a circuit board; and
a fastener assembly connecting the circuit board to the wall of the housing, the fastener including
a bush comprising an opening and connected to the circuit board by a soldered joint,
a thread part within the opening of the bush and comprising a female locking thread, and
a screw including a male thread and passing through the wall of the housing and engaged with the female thread, such that the male thread is locked in position by the female thread.

18. The electronic system of claim 17, wherein the thread part is at least one one of a helicoil, a tang-less helicoil, a press-fit in the bush, and a screw-fit in the bush.

19. The electronic system of claim 17, wherein the fastener provides thermal contact between the circuit board and the wall of the housing.

20. An avionic system comprising the electronic system of claim 17.
